(19) United States
(12) Patent Application Publication
(10) Pub. No.: US 2020/0190662 A1
(43) Pub. Date: Jun. 18, 2020

(54) SYSTEMS AND METHODS FOR GENERATING ALIGNED CARBON NANOTUBES

(71) Applicant: Carbon Technology, Inc., San Clemente, CA (US)

(72) Inventors: Mark Chapman, Irvine, CA (US); Dawei Wang, Irvine, CA (US)

(21) Appl. No.: 16/711,122

(22) Filed: Dec. 11, 2019

Related U.S. Application Data
(60) Provisional application No. 62/778,523, filed on Dec. 12, 2018.

(51) Int. Cl. C23C 16/26; C23C 16/50

(52) U.S. Cl. CPC C23C 16/26; C23C 16/50

(57) ABSTRACT

Aligned carbon nanotube are synthesized using an electric potential generated by a thermocouple and strips of first and second materials. The first and second materials have different chemical compositions, and include at least one of an oxide and a metal. A catalyst is deposited on and/or around the materials, and can also be deposited on the substrate. The substrate is exposed to the electric potential in the presence of a carbon-containing gas during chemical vapor deposition. This causes carbon nanotubes to grow from the catalyst, in alignment with the electric potential.

This application claims the benefit of priority of U.S. Provisional Application No. 62/778,523, filed Dec. 12, 2018. These and all other referenced extrinsic materials are incorporated herein by reference in their entirety.

### FIELD OF THE INVENTION

The field of the invention is carbon nanotube synthesis, and more particularly techniques for controllably aligning carbon nanotubes on solid substrates for use in field effect transistors.

### BACKGROUND

While their potential utility has been documented, carbon nanotubes (CNT) have yet to be utilized as components of integrated circuits on a large scale. In theory, such use can seem relatively straightforward. A source contact and a drain contact that have been formed by microfabrication techniques on a suitable substrate can be connected by one or more bridging carbon nanotubes, to form the basis of a functional electronic device. For example, the addition of a gate contact can permit such a device to act as a field effect transistor (FET). Large-scale manufacturing of integrated circuits incorporating such devices, however, requires accurate and ordered placement of appropriately dimensioned carbon nanotubes in reasonable density (# of CNTs per unit length). As such there remain critical technical hurdles to the utilization of nanotubes in integrated circuits.

High-performance CNT FET benefit from well aligned CNTs in the channel tube, since crossings can detract from performance due to percolation network effects. One approach to manufacturing CNT FETs has been to make appropriately dimensioned carbon nanotubes in solution, and then distribute them over the surface of a silicon or other substrate that can be used for the production of devices. Such approaches, however, usually end up with CNTs containing contaminants and surfactants left over from the deposition process, and which contain defects. The more straightforward approach is to deposit the catalyst on a substrate, then directly grow the CNTs, for example, as described in the U.S. Pat. No. 6,346,189 (filed Aug. 14, 1998, to H. Dai et al.).

All publications herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

The direct growth method can produce CNTs with high quality, but the results on a Si substrate lack alignment. For example, researchers have demonstrated aligned growth of CNTs on a single crystal substrate, see United States Patent Application US 2012/0,321,785 (filed Aug. 28, 2012, to J. A. Rogers et al.), which describes the use of crystal lattice structure on quartz to guide carbon nanotubes during synthesis to orient the CNTs along crystal steps. Such an approach, however, necessarily limits the synthesis of CNTs on a restricted set of substrate materials, and the strong interaction between the CNTs and the single crystal substrate has been shown to detrimentally affect the electrical performance of the CNTs.

United States Patent Application US 2006/0,006,377 (filed Jun. 6, 2005, to J. A. Golovchenko) describes depositing catalyst on top of some electrical electrodes, and then applying a voltage to these electrodes to produces an electrical field that guides the growth of carbon nanotubes. Unfortunately, the necessity of reliably and safely supplying such a voltage to the electrodes in a high-temperature CVD furnace complicates the manufacturing process. Radu et al. (I. Radu, Y. Hanein, and D. H. Cobden; “Oriented Growth of Single-Wall Carbon Nanotubes using Alumina Patterns”, Nanotechnology 15 (2004):473-476) reported that carbon nanotubes produced from catalyst distributed over the surface of a substrate were oriented essentially perpendicular to the surfaces of nearby alumina features, which had been deposited on the substrate earlier. This is believed to be due to the electrical field induced by the accumulated charges between the deposited alumina and the substrate material. Such electrical fields, however, will cancel each out when multiple parallel strips of alumina are formed on the Si/SiO2 surface, because of the same type of charge developed at each strip.

Thus, there is still a need for simple and reliable apparatus, systems and methods that provide controlled and aligned growth of carbon nanotubes, at high densities, on a substrate suitable for manufacturing integrated circuits.

### SUMMARY OF THE INVENTION

The inventive subject matter provides apparatus and systems, and methods by which single-walled carbon nanotubes can be synthesized, in situ, in an oriented/aligned fashion, on a substrate suitable for integrated circuit manufacture.

In general, the process comprises generating an electric field using a material comprising at least one of the group consisting of (a) a thermocouple, and (b) a first material (M1) paired with a second material (M2), depositing a catalyst on and/or around the materials, and exposing the substrate to a carbon containing gas using chemical vapor deposition. This allows the carbon nanotubes to grow from the catalyst in a manner aligned at least in part by the potential generated in the electric field.

The first material can be a first oxide material including aluminum oxide (Al₂O₃), and the second material can be a second oxide material, for example, Tantalum oxide (Ta₂O₅) or metal. The metal includes at least one of metals consisting of Molybdenum (Mo), Tantalum (Ta), and the combination thereof.

In some embodiments, the first and the second strips can be positioned in parallel. The catalyst is deposited on and/or around each of the first and second strips. In some embodiments, the catalyst is deposited in discrete locations on each of the first and second strips. In another embodiment, the catalyst is deposited directly on the substrate.

In some embodiments, the thermocouple can be a thermopile. The thermopiles can be connected seriously to meet the electrical field to a desired value.

The substrate can be at least one of the group consisting of a silicon wafer, a quartz wafer and may have an oxide layer on or in the substrate.

In some embodiments, the substrate is exposed to the carbon containing gas at a temperature between 500° C. to about 1200° C., inclusive. In another embodiment, synthesizing of the aligned carbon nanotubes can occur in a furnace, and modulating a temperature of the furnace may alter orientation of the produced carbon nanotubes.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1 shows a catalyst and an array of paired materials (M1&M2) deposited on a substrate to obtain aligned carbon nanotubes.

FIG. 2A shows a side-view of growth of aligned carbon nanotubes utilizing thermopiles.

FIG. 2B shows a top-view of growth of aligned carbon nanotubes utilizing thermopiles.

### DETAILED DESCRIPTION

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

The recitation of ranges of values herein is merely intended to serve as a shorthand method of referring individually to each separate value falling within the range. Unless otherwise indicated herein, each individual value is incorporated into the specification as if it were individually recited herein.

Unless the context dictates the contrary, all ranges set forth herein should be interpreted as being inclusive of their endpoints, and open-ended ranges should be interpreted to include only commercially practical values. Similarly, all lists of values should be considered as inclusive of intermediate values unless the context indicates the contrary.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

The inventive subject matter provides apparatus, systems, and methods by which single-walled carbon nanotubes can be synthesized, in situ, in an oriented/aligned fashion, on a substrate suitable for integrated circuit manufacture. In general, the process comprises generating an electric field using a material comprising at least one of the group consisting of (a) a thermocouple, and (b) a first material (M1) paired with a second material (M2), depositing a catalyst on and/or around the materials, and exposing the substrate to a carbon containing gas using chemical vapor deposition. This allows the carbon nanotubes to grow from the catalyst in a manner aligned at least in part by the potential generated in the electric field.

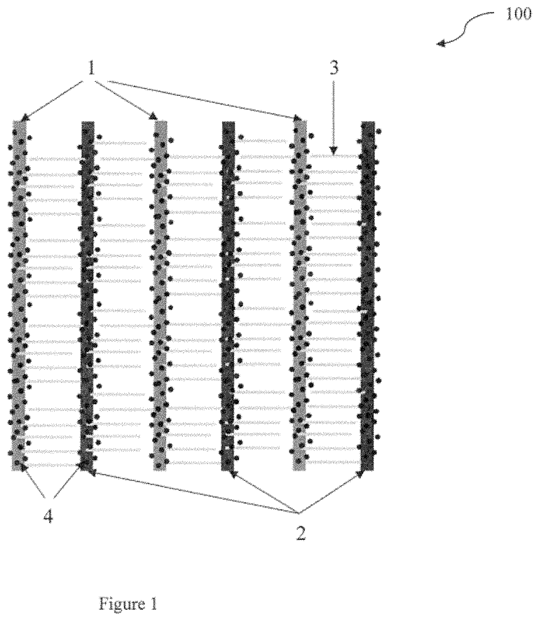

FIG. 1 illustrates an embodiment of the inventive subject matters, utilizing a catalyst and an array of deposited features of a first material (M1, 1) paired with the second material (M2, 2) to obtain aligned carbon nanotubes. M1(1) can be an oxide material including aluminum oxide (Al₂O₃). M2(2) can be an oxide material including Tantalum oxide (Ta₂O₅) or metal including Molybdenum and Tantalum. Each of M1(1) and M2(2) has a structure of a strip, which can be linear, slightly curved, or slightly zigzagged.

M1(1) and M2(2) can be deposited on the substrate in parallel, using any suitable technique, including at least one of photoresist lift-off process, vapor deposition, atomic layer deposition, sputtering, e-beam deposition, and/or molecular beam epitaxy. Contemplated substrates include at least one of a silicon wafer, a quartz wafer, and the substrate can be coated with an oxide layer.

The lengths of each of M1(1) and M2(2) are preferably less than 100 μm, more preferably less than 50 μm. The widths of each of M1(1) and M2(2) are preferably less than 5 μm, more preferably less than 2 μm. The thicknesses of each of M1(1) and M2(2) are preferably less than 1 μm, more preferably less than 200 nm. M1 and M2 are preferably separated by less than 50 μm, more preferably less than 10 μm.

A catalyst (4) that promotes the growth of carbon nanotubes (CNTs, 3) is deposited on and/or around M1(1) and M2 (2). Suitable catalysts (4) include at least one of iron (Fe,) cobalt (Co), nickel (Ni), ruthenium (Ru), rhodium (Rh), iridium (Ir), platinum (Pt), molybdenum (Mo), tungsten (W), chromium (Cr), alloys thereof, and oxides thereof. The catalyst can be provided as a solution, suspension, nanoparticles, or any combination thereof. A catalyst can be provided as a coating or layer supported by a microparticle. A catalyst can be deposited as a precursor (for example, a nitrate) that is converted to the desired catalytic species at a subsequent point in the manufacturing process (for example, catalyst deposition through heating). Similarly, a catalyst can be deposited in an encapsulated form; for example, iron oxide can be deposited on the protein ferritin.

The catalyst (4) can be deposited on and/or around M1(1) and M2 (2) by any suitable process, including, but not limited to, a photoresist lift-off process that followed by deposition of a solution, suspension, and/or slurry of catalyst, then followed by resist removal. Alternatively, methods for catalyst deposition can include atomic layer deposition, sputtering, e-beam deposition, thermal evaporation molecular beam epitaxy, and/or sol-gel formation.

As noted above, M1(1) and M2 (2) are selected such that an electric potential is developed between these two materials under CNT (3) synthesis conditions. As such an electric field is created that is nearly perpendicular to the major axis of M1(1) an M2(2) over at least a portion of synthesizing CNTs (3). The center of the electrical field between the strips is enhanced due to the different types of charges developed at each strip. This makes our invention different from using only Alumina under the catalyst, which would result in the electrical fields from the two strips canceling each other out. Since CNT growth is influenced by the presence of electric fields, proceeding as outlined herein will cause CNT growth to be essentially perpendicular to the major axis of the strips, which aligns the synthesized CNTs (3). It is also contemplated that M1(1) and M2 (2) can be arranged as an array of alternating bands or strips of deposited M1(1) and M2(2).

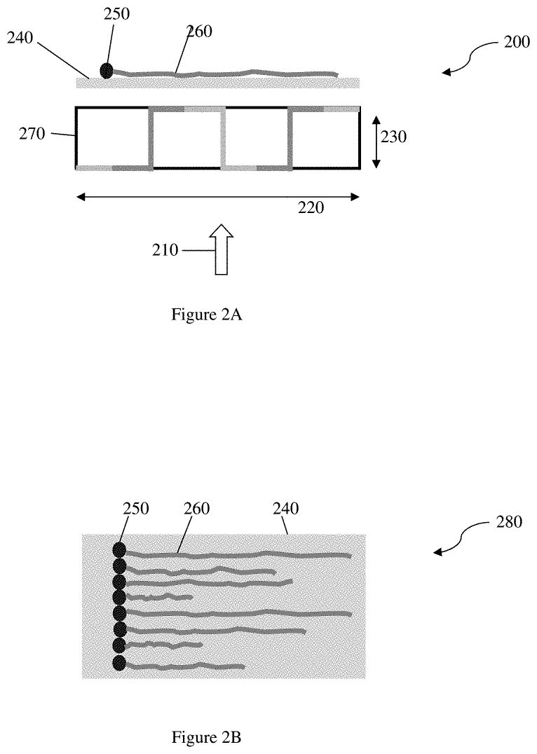

FIG. 2A illustrates a cross-sectional view of an embodiment of the inventive subject matters, utilizing thermocouples to obtain aligned carbon nanotubes. Thermocouples can be thermopiles. When heat (210) is applied from the bottom of the thermopiles (270), the bottom surface of the thermopile is hotter than the top surface. The temperature differential in the thermopile, ΔT, (230) is directly proportional to the output voltage or the electric potential ΔV, (220). Thus, the electric potential can be tuned by adjusting the external temperature and the number of thermocouples (thermopiles) junction pairs. As shown in FIG. 2A, a substrate (240) with a catalyst (250) is exposed to a field of electric potential (220), guiding CNT (260) growing in aligned orientation. Suitable catalysts and the method of catalyst deposition are described above.

FIG. 2B illustrates a top view of an embodiment of the inventive subject matters, utilizing thermopiles to obtain aligned carbon nanotubes. The catalyst (250) is deposited on the substrate (240) and CNTs (260) start growing from the catalyst according partially to electric potential.

The growth of CNTs from such deposited catalyst can be achieved in chemical vapor deposition by (a) exposing the catalyst to carbon-containing gases (or mixtures including carbon-containing gases) at high temperatures and (b) exposing the substrate to the field of the electric potential described above. Because the catalyst is exposed to the electric potential and carbon nanotubes are synthesized partially according to the electric potential, the CNTs are synthesized in aligned orientation as shown in FIG. 2B.

It should be appreciated that optimal synthesis of CNTs can require the use of one or more carbon sources at a selected temperature. Contemplated carbon-containing gases include carbon monoxide, oxygenated hydrocarbons such as acetone and methanol, aromatic hydrocarbons such as toluene, benzene and naphthalene, and any combination thereof. Examples of suitable hydrocarbons include, but are not limited to aliphatic hydrocarbons, both saturated and unsaturated, including methane, ethane, propane, butane, hexane, acetylene, ethylene, propylene, and any combination thereof. Such gases can be applied at temperatures ranging from 500° C. to about 1200° C. Different conditions can be selected to produce desired lengths and/or densities of CNTs, for manufacture of integrated circuit elements or other uses.

Since a thermopile converts thermal energy to electrical energy, one can select the temperature to affect the electrical energy between the strips of materials, and thereby assist in aligning the carbon nanotubes and/or adjusting the length of CNT growth.

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A method for synthesizing aligned carbon nanotubes, comprising;
generating an electric field using a material comprising at least one of the group consisting of (a) a thermocouple, and (b) a first material (M1) paired with a second material (M2);
depositing a catalyst on and/or around the materials; and
exposing a substrate to a carbon containing gas using chemical vapor deposition, such that the carbon nanotubes grow from the catalyst in a manner aligned at least in part by a potential generated in the electric field.

2. The method of claim 1, wherein the first material is a first oxide material including aluminum oxide (Al₂O₃).

3. The method of claim 1, wherein the second material is a second oxide material or metal.

4. The method of claim 3, wherein the second oxide material includes Tantalum oxide (Ta₂O₅).

5. The method of claim 3, wherein the metal comprises at least one of metals consisting of Molybdenum (Mo), and Tantalum (Ta).

6. The method of claim 1, wherein the thermocouple is a thermopile.

7. The method of claim 1, further comprising applying heat to the surface of thermopiles against the substrate to generate an electric field.

8. The method of claim 7, wherein the electric field is adjusted to a desired value by connecting multiple instances of the thermopile.

9. The method of claim 1, wherein the substrate comprises at least one of the group consisting of a silicon wafer, a quartz wafer.

10. The method of claim 1, wherein the substrate has an oxide layer.

11. The method of claim 6, further comprising positioning the first strip and the second strip in parallel.

12. The method of claim 6, further comprising depositing the catalyst on and/or around each of the first and second strips.

13. The method of claim 6, further comprising depositing the catalyst in discrete locations on each of the first and second strips.

14. The method of claim 1, further comprising depositing the catalyst directly on the substrate.

15. The method of claim 1, further comprising exposing the substrate to the carbon containing gas at a temperature between 500° C. to about 1200° C., inclusive.

16. The method of claim 1, wherein synthesizing of the aligned carbon nanotubes occurs in a furnace, and further comprising modulating a temperature of the furnace to alter orientation of the produced carbon nanotubes.
